(19) United States
(12) Patent Application Publication
(10) Pub. No.: US 2007/0147018 A1
(43) Pub. Date: Jun. 28, 2007

(54) FOLIO SHIELDING MECHANISM

(75) Inventors: JEN YU WANG, Taipei Hsien (TW); LING MIAO HUNG, Taipei Hsien (TW)

Correspondence Address: J C PATENTS, INC., 4 VENTURE, SUITE 250, IRVINE, CA, 92618, US

(73) Assignee: COOLER MASTER CO.,LTD., Taipei Hsien (TW)

(21) Appl. No.: 11/461,540

(22) Filed: Aug. 1, 2006

(30) Foreign Application Priority Data
Dec. 27, 2005 (TW) 94222725

(51) Int. Cl. H05K 9/00

(52) U.S. Cl. 361/816

(57) ABSTRACT

A folio shielding mechanism suitable for protecting an operation surface of a host is provided. The folio shielding mechanism includes a first shell, a second shell, and a transmission module. The transmission module is disposed on a first supporting surface of the host adjacent to the operation surface, and is connected to the first shell and the second shell. When the first shell is moving towards a first direction, the second shell is driven by the first shell through the transmission module and moving towards a second direction opposite to the first direction, so that the first shell and the second shell would be either joined together above the operation surface for covering the operation surface or apart from each other for exposing the operation surface.

### CROSS-REFERENCE TO RELATED APPLICATION

This application claims the priority benefit of Taiwan application serial no. 94222725, filed on Dec. 27, 2005. All disclosure of the Taiwan application is incorporated herein by reference.

### BACKGROUND OF THE INVENTION

1. Field of the Invention

The present invention relates to a shielding structure of a host, and more particular, to a folio shielding mechanism of a host.

2. Description of Related Art

Currently, computers have undoubtedly become one of the essential products in our daily life in the multimedia information era. Computers such as servers, workstations, desktop computers, laptop computers, and even industrial computers have gradually become an indispensable tool in our daily life and work place of ordinary people.

A desktop computer mainly comprises a host, a display, and peripheral equipments, wherein the host has an operation surface. In order to protect the operation surface of the host, a shield plate is additionally disposed on the host in the conventional art, in which the shield plate is pivoted on one side of the operation surface with respect to a pivot, such that the shield plate rotates about the pivot serving as a rotation axis relative to the operation surface. Thus, a user can make the shield plate being at a close position or an open position depending on actual requirements. In the close position, the shield plate covers the operation surface. At this time, the operation surface is protected by the shield plate. When the user turns the shield plate to the open position from the close position, the operation surface is not covered by the shield plate. At this time, the user operates the optical disc drive in the host through the operation surface.

In view of the above, although the design of the shield plate can be used to protect the operation surface of the host, this design requires a relatively large space. That is to say, a sufficient space for rotation is required around the host, such that the shield plate can move between the open position and the close position, which causes inconvenience to the user.

### SUMMARY OF THE INVENTION

An objective of the present invention is to provide a folio shielding mechanism, which requires a comparatively smaller space to achieve the opening and closing of the folio shielding mechanism.

The present invention provides a folio shielding mechanism, which is suitable for protecting an operation surface of a host. The folio shielding mechanism comprises a first shell, a second shell and a first transmission module. The first transmission module is disposed on a first supporting surface of the host adjacent to the operation surface, and is connected to the first shell and the second shell. When the first shell is moving towards a first direction, the second shell is driven by the first shell through the first transmission module and moving towards a second direction opposite to the first direction, so that the first shell and the second shell are either joined together above the operation surface for covering the operation surface or apart from each other for exposing the operation surface.

According to the folio shielding mechanism as described in an embodiment of the present invention, the first transmission module comprises a first transmission component and a second transmission component. The first transmission component is pivoted on the first supporting surface with respect to a first pivot, and is connected to the first shell. The first shell and the first transmission component are suitable for rotating about the first pivot serving as a rotation axis towards the first direction. The second transmission component is pivoted on the first supporting surface with respect to a second pivot, and is connected to the second shell and also connected to the first transmission component. The second transmission component is suitable for being driven by the first transmission component, and rotates about the second pivot serving as a rotation axis towards the second direction.

According to the folio shielding mechanism as described in an embodiment of the present invention, the folio shielding mechanism further comprises a damper connected to one of the first transmission component and the second transmission component, for limiting the rotation speeds of the first transmission component and the second transmission component.

According to the folio shielding mechanism as described in an embodiment of the present invention, the first transmission component comprises a first gear pivoted on the first supporting surface with respect to the first pivot. The second transmission component comprises a second gear pivoted on the first supporting surface with respect to the second pivot. And the first gear is engaged with the second gear.

According to the folio shielding mechanism as described in an embodiment of the present invention, the first transmission component further comprises a first link lever having one end connected to the first gear, such that the first link lever rotates about the first pivot serving as a rotation axis towards the first direction, and having the other end connected to the first shell. In addition, the folio shielding mechanism further comprises a stopper fixed on the first supporting surface. When the first shell and the second shell are joined together, the stopper contacts the first link lever.

According to the folio shielding mechanism as described in an embodiment of the present invention, the second transmission component further comprises a second link lever having one end connected to the second gear, such that the second link lever rotates about the second pivot serving as a rotation axis towards the second direction, and having the other end connected to the second shell. In addition, the folio shielding mechanism further comprises a stopper fixed on the first supporting surface. When the first shell and the second shell are joined together, the stopper contacts one of the first link lever and the second link lever.

According to the folio shielding mechanism as described in an embodiment of the present invention, the folio shielding mechanism further comprises a second transmission module disposed on a second supporting surface of the host opposite to the first supporting surface, and is connected to the first shell and the second shell. When the first shell is moving towards a first direction, the second shell is driven by the first shell through the first transmission module and the second transmission module and moving towards a second direction.

The present invention provides a folio shielding mechanism, which is suitable for protecting an operation surface of a host. The folio shielding mechanism comprises a first shell, a second shell, and a first transmission module. The first transmission module is disposed on a first supporting surface of the host adjacent to the operation surface, and is connected to the first shell and the second shell. The first transmission module comprises a first transmission component and a second transmission component. The first transmission component is pivoted on a first supporting surface of the host adjacent to the operation surface with respect to a first pivot, and is connected to the first shell. The first shell and the first transmission component are suitable for rotating about the first pivot serving as a rotation axis towards the first direction. The second transmission component is pivoted on the first supporting surface with respect to a second pivot, and is connected to the second shell and also connected to the first transmission component. When the first transmission component rotates about the first pivot serving as a rotation axis towards the first direction, the second transmission component is suitable for being driven by the first transmission component and rotates about the second pivot serving as a rotation axis towards a second direction opposite to the first direction, so that the first shell and the second shell are either joined together above the operation surface for covering the operation surface or apart from each other for exposing the operation surface.

According to the folio shielding mechanism as described in an embodiment of the present invention, the folio shielding mechanism further comprises a damper connected to one of the first transmission component and the second transmission component, for limiting the rotation speeds of the first transmission component and the second transmission component.

According to the folio shielding mechanism as described in an embodiment of the present invention, the first transmission component comprises a first gear pivoted on the first supporting surface with respect to the first pivot. The second transmission component comprises a second gear pivoted on the first supporting surface with respect to the second pivot. And the first gear is engaged with the second gear.

According to the folio shielding mechanism as described in an embodiment of the present invention, the first transmission component further comprises a first link lever having one end connected to the first gear, such that the first link lever rotates about the first pivot serving as a rotation axis towards the first direction, and having the other end connected to the first shell. In addition, the folio shielding mechanism further comprises a stopper fixed on the first supporting surface. When the first shell and the second shell are joined together, the stopper contacts the first link lever.

According to the folio shielding mechanism as described in an embodiment of the present invention, the second transmission component further comprises a second link lever having one end connected to the second gear, such that the second link lever rotates about the second pivot serving as a rotation axis towards the second direction, and having the other end connected to the second shell. In addition, the folio shielding mechanism further comprises a stopper fixed on the first supporting surface. When the first shell and the second shell are joined together, the stopper contacts one of the first link lever and the second link lever.

According to the folio shielding mechanism as described in an embodiment of the present invention, the folio shielding mechanism further comprises a second transmission module disposed on a second supporting surface of the host opposite to the first supporting surface, and is connected to the first shell and the second shell. When the first shell is moving towards the first direction, the second shell is driven by the first shell through the first transmission module and the second transmission module, and is moving towards a second direction.

The present invention provides a folio shielding mechanism, which is suitable for protecting an operation surface of a host. The folio shielding mechanism comprises a first shell, a second shell, and a first transmission module. The first transmission module is disposed on a first supporting surface of the host adjacent to the operation surface, and is connected to the first shell and the second shell. The first transmission module comprises a first transmission component and a second transmission component. The first transmission component comprises a first gear and a first link lever. The first gear is pivoted on a first supporting surface of the host adjacent to the operation surface with respect to a first pivot. One end of the first link lever is connected to the first gear, and the other end of the first link lever is connected to the first shell. The first gear and the first link lever are suitable for rotating about the first pivot serving as a rotation axis towards a first direction. The second transmission component comprises a second gear and a second link lever. The second gear is pivoted on the first supporting surface of the host with respect to a second pivot, and is engaged with the first gear. One end of the second link lever is connected to the second gear, and the other end of the second link lever is connected to the second shell. When the first gear rotates about the first pivot serving as a rotation axis towards the first direction, the second gear is driven by the first gear, and rotates towards a second direction opposite to the first direction, so that the first shell and the second shell are either joined together above the operation surface for covering the operation surface or apart from each other for exposing the operation surface.

According to the folio shielding mechanism as described in an embodiment of the present invention, the folio shielding mechanism further comprises a damper connected to one of the first gear and the second gear, for limiting the rotation speeds of the first gear and the second gear. In addition, the folio shielding mechanism further comprises a stopper fixed on the first supporting surface. When the first shell and the second shell are joined together, the stopper contacts one of the first link lever and the second link lever.

The present invention employs the design of two protective shells (i.e., the first shell and the second shell), the rotation axis for the first shell and the second shell is located on the first supporting surface, and the moving direction of the first shell is opposite to that of the second shell. Therefore, compared with the design of a single shield plate pivoted on one side of the operation surface in the conventional art, the present invention achieves the combination and separation of the first shell and the second shell in a comparatively smaller space.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a perspective view of a folio shielding mechanism in an open state according to an embodiment of the present invention.

FIG. 2 is a top view of the folio shielding mechanism of FIG. 1 in the open state.

FIG. 3 is a perspective view of the folio shielding mechanism of FIG. 1 in a close state.

FIG. 4 is a top view of the folio shielding mechanism of FIG. 1 in the close state.

FIG. 5 is a perspective view of a folio shielding mechanism according to another embodiment of the present invention.

### DESCRIPTION OF EMBODIMENTS

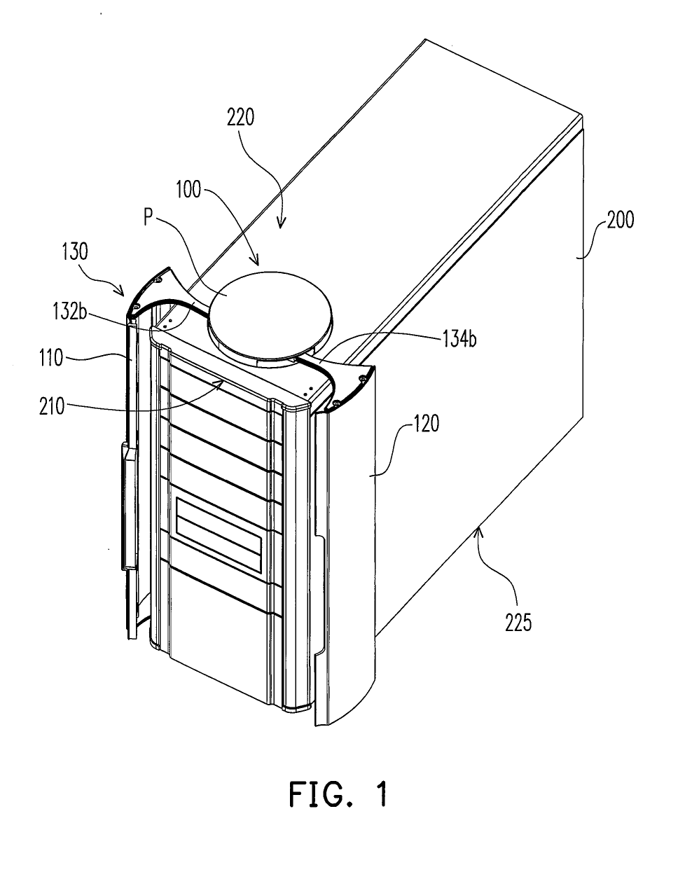

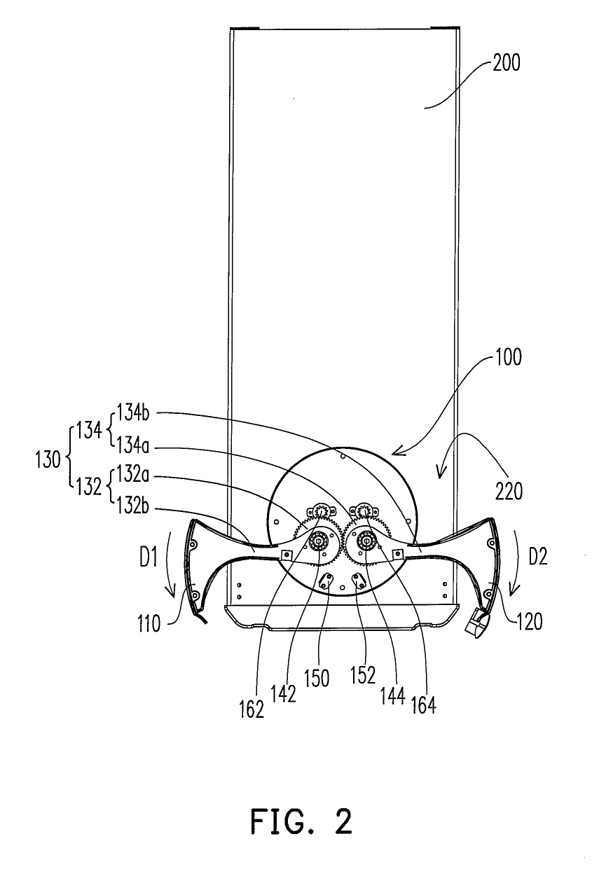

FIG. 1 is a perspective view of a folio shielding mechanism in an open state according to an embodiment of the present invention. FIG. 2 is a top view of the folio shielding mechanism of FIG. 1 in a open state. Referring to FIGS. 1 and 2 together, the folio shielding mechanism 100 is suitable for protecting an operation surface 210 of a host 200. The folio shielding mechanism 100 mainly comprises a first shell 110, a second shell 120, and a first transmission module 130. In the present embodiment, generally, the folio shielding mechanism 100 further comprises a protective cover P as shown in FIG. 1, which is covered on the first supporting surface 220 for protecting sub elements of the first transmission module 130. However, in order to clearly illustrate the relationship between the components and the action of the first transmission module 130, FIG. 2 is a top view of the folio shielding mechanism 100 with the protective cover P being removed.

The first transmission module 130 is disposed on a first supporting surface 220 of the host 200 adjacent to the operation surface 210, and is connected to both the first shell 110 and the second shell 120. The first transmission module 130 mainly comprises a first transmission component 132 and a second transmission component 134. The first transmission component 132 mainly comprises a first gear 132a and a first link lever 132b. The first gear 132a is pivoted on the first supporting surface 220 with respect to a first pivot 140. One end of the first link lever 132b is connected to the first gear 132a, and the other end of the first link lever 132b is connected to the first shell 110.

The second transmission component 134 comprises a second gear 134a and a second link lever 134b. The second gear 134a is pivoted on the first supporting surface 220 with respect to a second pivot 145, and the second gear 134a is engaged with the first gear 132a. One end of the second link lever 134b is connected to the second gear 134a, and the other end of the second link lever 134b is connected to the second shell 120.

When the user intends to use the folio shielding mechanism 100 to protect the operation surface 210, the user, for example, exerts an external force to the first shell 110, such that the first shell 110, the first link lever 132b, and the first gear 132a all rotate about the first pivot 142 serving as a rotation axis towards a first direction D1. Furthermore, when the first shell 110, the first link lever 132b, and the first gear 132a rotate towards a first direction D1, the second gear 134a is driven by the first gear 132a to rotate towards a second direction D2 opposite to the first direction D1. Therefore, as the second gear 134a rotates, the second link lever 134b and the second shell 120 also rotate about the second pivot 144 serving as a rotation axis towards the second direction D2.

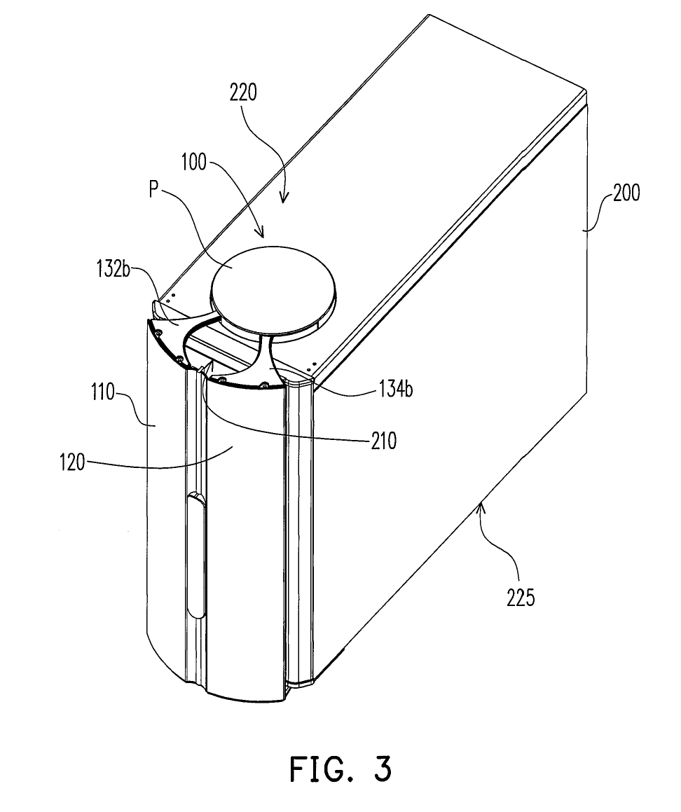

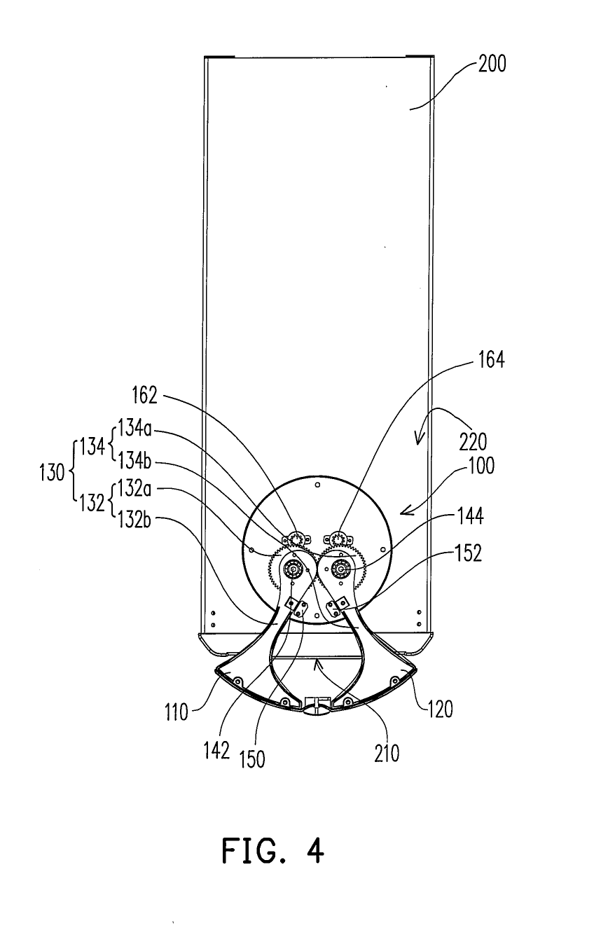

Thus, the first shell 110 and the second shell 120 gradually get close to each other. When the first shell 110 contacts the second shell 120, the folio shielding mechanism 100 is in a close state, as shown in FIGS. 3 and 4. FIG. 3 is a perspective view of the folio shielding mechanism of FIG. 1 when being in a close state. FIG. 4 is a top view of the folio shielding mechanism of FIG. 1 when being in a close state. At this time, the first shell 110 and the second shell 120 are located above the operation surface 210 for covering the operation surface 210.

Similar to the above, when the folio shielding mechanism 100 is subjected to an external force and changes from the close state to an open state, the first shell 110, the second shell 120, and the first transmission module 130 of the folio shielding mechanism 100 act in opposite manner, and the details will not be described herein again.

In addition, when the folio shielding mechanism 100 changes from the close state to the open state, in order to prevent the excess collision between the first shell 110 and the second shell 120 which may otherwise damage the first shell 110 or the second shell 120, a first stopper 150 is further fixed on the first supporting surface 220 in the present embodiment. When the first shell 110 and the second shell 120 are joined together, the first stopper 150 contacts the first link lever 132b, thus preventing the collision between the first shell 110 and the second shell 120, and thereby avoiding damaging the first shell 110 or the second shell 120. Definitely, a second stopper 152 is further disposed on the first supporting surface 220 in the present embodiment, for limiting the movement of the second link lever 134b, and the details will not be described herein again.

In view of the above, a first damper 160 is further disposed on a first supporting surface 220 in the present embodiment, and is connected to the first gear 132a for limiting the rotation speeds of the first gear 132a and the second gear 134a. Through limiting the rotation speeds of the first gear 132a and the second gear 134a, the present embodiment further reduces the collision strength when the first shell 110 contacts the second shell 120, thereby avoiding damaging the first shell 110 and the second shell 120 when contacting each other. Definitely, a second damper 162 is further disposed on the first supporting surface 220 in the present embodiment. The second damper 162 is connected to the second gear 134a, and the details will not be described herein again.

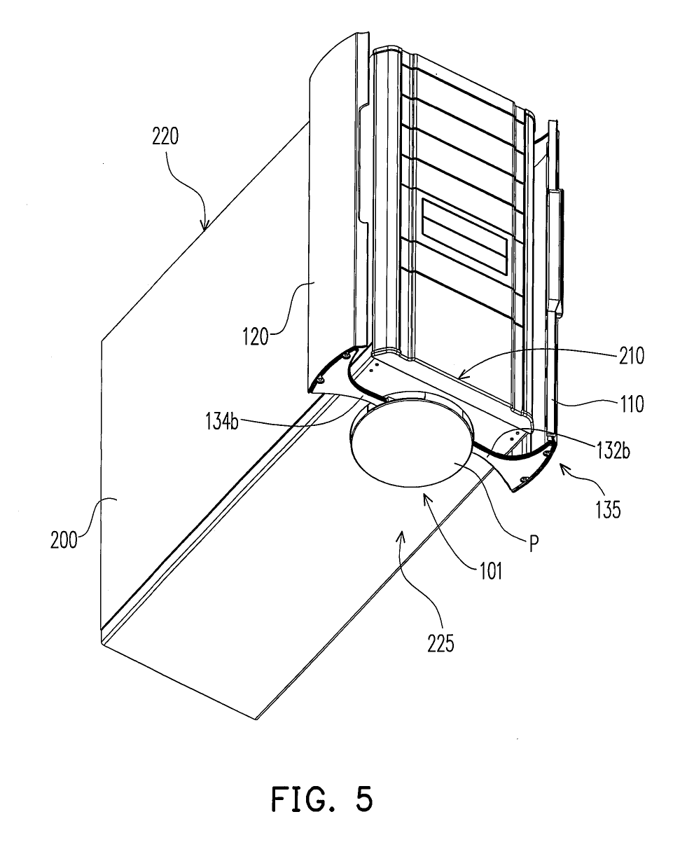

Furthermore, the folio shielding mechanism 100 in the present embodiment further comprises a second transmission module. FIG. 5 is a perspective view of a folio shielding mechanism according to another embodiment of the present invention, and FIG. 5 is a bottom view looking from the second supporting surface 225 of the host 200 to the first supporting surface 220. Referring to FIG. 5, the difference between the folio shielding mechanism 101 in FIG. 5 and the folio shielding mechanism 100 in FIG. 1 mainly lies in that in addition to having the first transmission module 130 of FIG. 1 on the first supporting surface 220, the folio shielding mechanism 101 in FIG. 5 further has a second transmission module 135 on the second supporting surface 225. The second transmission module 135 is similar to the first transmission module 130, and the same elements are indicated by the same numerals.

To sum up, the first shell and second shell of the present invention rotate about the first pivot and the second pivot located on the supporting surface serving as the rotation axis towards opposite directions, so that the first shell and the second shell move between the open state and close state with a small rotation radius. Therefore, the present invention achieves the combination and separation of the first shell and the second shell in a small space.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A folio shielding mechanism, suitable for protecting an operation surface of a host, comprising:
a first shell;
a second shell; and
a first transmission module, disposed on a first supporting surface of the host adjacent to the operation surface, and connected to the first shell and the second shell, wherein when the first shell is moving towards a first direction, the second shell is driven by the first shell through the first transmission module and moves towards a second direction opposite to the first direction, so that the first shell and the second shell are either joined together above the operation surface for covering the operation surface or apart from each other for exposing the operation surface.

2. The folio shielding mechanism as claimed in claim 1, wherein the first transmission module comprises:
a first transmission component, pivoted on the first supporting surface with respect to a first pivot, and connected to the first shell, wherein the first shell and the first transmission component rotate about the first pivot serving as a rotation axis towards the first direction; and
a second transmission component, pivoted on the first supporting surface with respect to a second pivot, and connected to the second shell and connected to the first transmission component, wherein the second transmission component is driven by the first transmission component and rotates about the second pivot serving as a rotation axis towards the second direction.

3. The folio shielding mechanism as claimed in claim 2, further comprising a damper connected to one of the first transmission component and the second transmission component, for limiting rotation speeds of the first transmission component and the second transmission component.

4. The folio shielding mechanism as claimed in claim 2, wherein the first transmission component comprises a first gear pivoted on the first supporting surface with respect to the first pivot, the second transmission component comprises a second gear pivoted on the first supporting surface with respect to the second pivot, and the first gear is engaged with the second gear.

5. The folio shielding mechanism as claimed in claim 4, wherein the first transmission component further comprises a first link lever having one end connected to the first gear, such that the first link lever rotates about the first pivot serving as a rotation axis towards the first direction, and having the other end connected to the first shell.

6. The folio shielding mechanism as claimed in claim 5, further comprising a stopper fixed on the first supporting surface, wherein when the first shell and the second shell are joined together, the stopper contacts the first link lever.

7. The folio shielding mechanism as claimed in claim 5, wherein the second transmission component further comprises a second link lever having one end connected to the second gear, such that the second link lever rotates about the second pivot serving as a rotation axis towards the second direction, and having the other end connected to the second shell.

8. The folio shielding mechanism as claimed in claim 7, further comprising a stopper fixed on the first supporting surface, wherein when the first shell and the second shell are joined together, the stopper contacts one of the first link lever and the second link lever.

9. The folio shielding mechanism as claimed in claim 1, further comprising a second transmission module disposed on a second supporting surface of the host opposite to the first supporting surface, and connected to the first shell and the second shell, wherein when the first shell is moving towards the first direction, the second shell is driven by the first shell through the first transmission module and the second transmission module, and moves towards the second direction.

10. A folio shielding mechanism, suitable for protecting an operation surface of a host, comprising:
a first shell;
a second shell; and
a first transmission module, disposed on a first supporting surface of the host adjacent to the operation surface, and connected to the first shell and the second shell, the first transmission module comprising:
a first transmission component, pivoted on a first supporting surface of the host adjacent to the operation surface with respect to a first pivot, and connected to the first shell, wherein the first shell and the first transmission component rotate about the first pivot serving as a rotation axis towards the first direction; and
a second transmission component, pivoted on the first supporting surface with respect to a second pivot, and connected to the second shell and connected to the first transmission component, wherein when the first transmission component rotates about the first pivot serving as a rotation axis towards the first direction, the second transmission component is driven by the first transmission component
and rotates about the second pivot serving as a rotation axis towards a second direction opposite to the first direction, so that the first shell and the second shell are either joined together above the operation surface for covering the operation surface or apart from each other for exposing the operation surface.

11. The folio shielding mechanism as claimed in claim 10, further comprising a damper connected to one of the first transmission component and the second transmission component, for limiting rotation speeds of the first transmission component and the second transmission component.

12. The folio shielding mechanism as claimed in claim 10, wherein the first transmission component comprises a first gear pivoted on the first supporting surface with respect to the first pivot, the second transmission component comprises a second gear pivoted on the first supporting surface with respect to the second pivot, and the first gear is engaged with the second gear.

13. The folio shielding mechanism as claimed in claim 12, wherein the first transmission component further comprises a first link lever having one end connected to the first gear, such that the first link lever rotates about the first pivot serving as a rotation axis towards the first direction, and having the other end connected to the first shell.

14. The folio shielding mechanism as claimed in claim 13, further comprising a stopper fixed on the first supporting surface, wherein when the first shell and the second shell are joined together, the stopper contacts the first link lever.

15. The folio shielding mechanism as claimed in claim 13, wherein the second transmission component further comprises a second link lever having one end connected to the second gear, such that the second link lever rotates about the second pivot serving as a rotation axis towards the second direction, and having the other end connected to the second shell.

16. The folio shielding mechanism as claimed in claim 15, further comprising a stopper fixed on the first supporting surface, wherein when the first shell and the second shell are joined together, the stopper contacts one of the first link lever and the second link lever.

17. The folio shielding mechanism as claimed in claim 10, further comprising a second transmission module disposed on a second supporting surface of the host opposite to the first supporting surface, and connected to the first shell and the second shell.

18. A folio shielding mechanism, suitable for protecting an operation surface of a host, comprising:
a first shell;
a second shell; and
a first transmission module, disposed on a first supporting surface of the host adjacent to the operation surface, and connected to the first shell and the second shell, the first transmission module comprising:
a first transmission component, comprising a first gear and a first link lever, wherein the first gear is pivoted on a first supporting surface of the host adjacent to the operation surface with respect to a first pivot, one end of the first link lever is connected to the first gear and the other end of the first link lever is connected to the first shell, and the first gear and the first link lever rotate about the first pivot serving as a rotation axis towards a first direction; and
a second transmission component, comprising a second gear and a second link lever, wherein the second gear is pivoted on the first supporting surface of the host with respect to a second pivot and is engaged with the first gear, one end of the second link lever is connected to the second gear and the other end of the second link lever is connected to the second shell, when the first gear rotates about the first pivot serving as a rotation axis towards the first direction, the second gear is driven by the first gear and rotates towards a second direction opposite to the first direction, so that the first shell and the second shell are either joined together above the operation surface for covering the operation surface or apart from each other for exposing the operation surface.

19. The folio shielding mechanism as claimed in claim 18, further comprising a damper connected to one of the first gear and the second gear, for limiting rotation speeds of the first gear and the second gear.

20. The folio shielding mechanism as claimed in claim 18, further comprising a stopper fixed on the first supporting surface, wherein when the first shell and the second shell are joined together, the stopper contacts one of the first link lever and the second link lever.

21. The folio shielding mechanism as claimed in claim 18, further comprising a second transmission module disposed on a second supporting surface of the host opposite to the first supporting surface, and connected to the first shell and the second shell.
